(19) United States
(12) Patent Application Publication
(10) Pub. No.: US 2002/0062465 A1
(43) Pub. Date: May 23, 2002

(54) LSI device failure analysis apparatus and analysis method thereof

(75) Inventor: Junichi Goto, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/992,732

(22) Filed: Nov. 14, 2001

(30) Foreign Application Priority Data
Nov. 17, 2000 (JP) 2000-351663

(51) Int. Cl. G01R 31/28

(52) U.S. Cl. 714/724

(57) ABSTRACT

The critical area calculation means (4), by accessing the relationship between the mask layout data of the target LSI device included in the design data (3) and the size and density of the extraneous materials including in the extraneous material distribution information (6), calculates the critical area of the failure node candidate, the results of this calculation being displayed by the critical area information display means (5). The displayed critical area information is support information, which indicates to be checked by physical means, of the failure node candidates.

### BACKGROUND OF THE INVENTION

1. Field of the Invention

The present invention relates to an LSI device failure analysis apparatus and a method for LSI device failure analysis, and more particularly to an LSI device failure analysis apparatus and method for failure analysis, using a critical area, whereby results of failure location prediction in a logic LSI device under analysis are displayed overlapped with the mask layout.

2. Related Art

Logic LSI device failure analysis is performed by predicting a location of a failure based on a failure log, which is the execution result from an LSI device tester, and then this location being analyzed using a physical means such as a scanning electron microscope (SEM).

With regard to failure location prediction, recent years have seen the development of practical software for predicting the location of a failure based on a failure log and the net list of the LSI device under analysis, one example being FastScan, made by Mentor Graphics Corporation in the US.

However, because the failure location prediction results are expressed as names of nodes in a net list, in order to identify the physical position of a failed location, it is necessary to identify the coordinates of a set of polygons of the mask layout data corresponding to the node names.

Practical software has also been developed to perform the task of establishing this relationship, this software providing a visual display of the predicted failure locations overlaid onto the mask layout using a GUI, and example of this software being LogicMap, made by Knights Technology, Inc. in the US.

This supports the failure location process, and makes it possible to analyze a failure location.

While the above-noted methods of failure analysis provide an improvement in efficiency in the process of identifying a failure location, the degree to which the efficiency is improved is dependent upon to what degree the failure candidate nodes can be narrowed down.

More specifically, the capability of the failure location prediction software is important. However, because presently available failure location prediction software is based on the assumption of a single failure, and does not necessarily sufficiently narrow down the failure candidates, so that its capabilities are insufficient. The reduction in the labor of such high-cost physical analysis such as analysis using the SEM is also insufficient.

Accordingly, it is an object of the present invention to provide an LSI device failure analysis apparatus and LSI device failure analysis method which displays failure location prediction results of an LSI device under analysis, superposing over a mask layout, wherein a critical area of mask layout data is used as information for identifying a failure location.

The term critical area as used above refers to a quantitative index indicating the degree to which a defect such as an extraneous material causes a short fault or an open fault.

For example, when an extraneous material attaches between interconnects, there is a possibility of a short occurring between the interconnects, but the degree of this possibility is governed by the spacing between the interconnects and the size (thought to be the diameter, assuming a circular shape) of the extraneous material. Although a short does not occur if the diameter of the extraneous material is smaller than the spacing between the interconnects, if it is larger than the spacing between the interconnects, whether or not a short occurs is determined by the positional relationship of the center coordinates of the extraneous material to the interconnects. Stated differently, a short will only occur in a case in which the center of the extraneous material is located within a specific region, and this region or the surface area thereof is referred to as the critical area.

### SUMMARY OF THE INVENTION

In order to achieve the above-noted objects, the present invention adopts the following basic technical constitution.

Specifically, a first aspect of the present invention is an LSI device failure analysis apparatus comprising: a layout data of an LSI device, failure node candidate data for a plurality of the LSI devices, extraneous material distribution information on a production line of the LSI device, a critical area calculation means for calculating a critical area corresponding to an arbitrary failure node of a failure node candidate data, by accessing the layout data and the extraneous material distribution information, and a critical area information display means for displaying the calculated critical area.

In the second aspect of the present invention, the critical area information display means displays a value of a critical area.

In the third aspect of the present invention, the critical area information display means displays the critical area by means of different intensity or color from surrounding graphics in response to the value of the critical area.

In the fourth aspect of the present invention, the critical area information display means calculates a frequency of occurrence of each failure node candidate of the failure node candidate data, and the critical area information display means displays a two-dimensional scatter diagram showing a relationship between the critical area and the frequency of occurrence of a corresponding failure node candidate.

In the fifth aspect of the present invention, the critical area information display means calculates a frequency of occurrence of each failure node candidate of the failure node candidate data, and the critical area calculation means calculates a critical area for each interconnect layer.

In the sixth aspect of the present invention, by selecting an arbitrary number of failure node candidates from the failure node candidate data and establishing an equation with regard to each of the selected failure node candidate in which a linear combination of each of the critical areas for each interconnect layer is equivalent to the frequency of occurrence, and setting up simultaneous equations having combination coefficients of the linear combinations as unknowns and combination coefficients obtained by solving the equations are taken as predicted amount of faults in each interconnect layer.

In the seventh aspect of the present invention, the extraneous material distribution information includes size information of the extraneous material and density information thereof.

In the eighth aspect of the present invention, the extraneous material distribution information includes position information of the extraneous material on the LSI device.

In the ninth aspect of the present invention, the apparatus further comprising a layout display means for displaying a layout of the LSI device, an arbitrary number of failure node candidates of the LSI device overlaid onto the layout and position information of an arbitrary number of the extraneous material overlaid onto the layout, based on the extraneous material distribution information.

Specifically, FIG. 1 shows a failure analysis apparatus according to an embodiment of the present invention. In the failure analysis apparatus shown in FIG. 1, a layout display means 1 displays mask layout data included in LSI device deign data 3 as graphics on a computer screen. For an arbitrary number of failure node candidates listed in an LSI device failure node candidate list 2, the corresponding mask layout data graphics are identified by accessing equipotential information included in the design data 3, these identified graphics being displayed in emphasized form, either by intensity or by color to set them apart from the other surrounding graphics. Additionally, by accessing mask layout data included in the design data 3 and extraneous material distribution information 6 on the LSI device production line, a critical area calculation means 4 calculates a critical area with regard to a failure node candidate that is displayed in an emphasized manner, and a critical area information display means 5 displays these calculation results.

Because the critical area is an index that indicates the likelihood that a fault such as a short or an open will occur, it can serve also as an indicator of the certainty of a failure node candidate displayed in emphasize manner by the layout display means being an actual failure node. Thus, by displaying the critical area of a failure node candidate, it is possible to obtain information that serves to effectively indicate from the plurality of failure node candidates listed in the failure node candidate list 2 a narrowed-down list of failure node candidates that should be checked using a physical means such as an SEM.

Usable methods of displaying the critical area include display of the critical area as a value, and graphics over the layout display as shown in FIG. 2.

Alternatively, it is possible to display a two-dimensional scatter diagram (FIG. 3), which indicates the correlation between each failure node candidate frequency of occurrence and the corresponding critical area. The failure node candidate list 2 is generated by using software to perform predicting failure node based on the target LSI device test results, which include the failure log, and the net list, and by executing this for a plurality of LSI devices, it is possible to obtain the frequency of occurrence for each failure node candidate.

Using a failure analysis apparatus according to the present invention, therefore, it is possible to create a display of the failure node candidates overlaid onto the layout display and to use the critical area of the failure node candidate as information to support the process of narrowing down the candidates.

### BRIEF DESCRIPTION OF THE DRAWINGS

FIG. 1 is a drawing showing the block diagram of the present invention.

FIG. 2 is a drawing showing an example of critical area information displayed on the computer screen according to the present invention.

FIG. 3 is a drawing showing another example of critical area information displayed on the computer screen according to the present invention.

FIGS. 4(a) and 4(b) are drawings illustrating a critical area.

FIG. 5 is a drawing showing an example of the calculation of a critical area according to the present invention.

### DETAILED DESCRIPTION OF THE PREFERRED EMBODIMENTS

Embodiments of the present invention are described in detail below, with references made to relevant accompanying drawings.

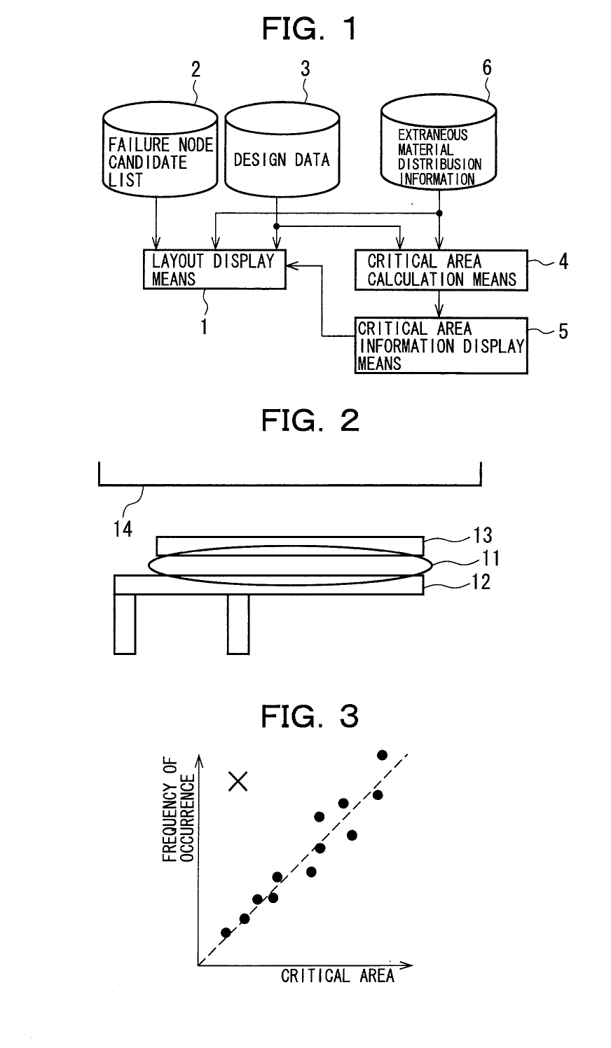

FIG. 1 shows an LSI device failure analysis apparatus according to an embodiment of the present invention.

This LSI device failure analysis apparatus has a layout display means 1, failure node candidate list data 2, design data 3, a critical area calculation means 4, a critical area information display means 5, and extraneous material distribution information 6.

The failure node candidate list 2 is the result of a prediction of a failure node based on the failure log results of an LSI device test, and on a net list of the LSI device. Practically usable software has already appeared for making the same output as the obtained failure log, so as to determine which nodes should be failure nodes.

The design data 3 includes mask layout data, a net list, and equipotential information of the target LSI device. The net list is the same data as used in the above-noted failure node prediction. The equipotential information is information that establishes a relationship for each node coded in the net list, to which graphics group of the mask layout data correspond.

The layout display means 1 is software that accesses the mask layout data included in the design data 3, so as to display the mask layout of the target LSI device in two dimensions on a computer screen.

The layout display means 1 accesses equipotential information for failure node candidates listed in the failure node candidate list 2, which is included in the design data by node name, so as to identify a graphics group within the mask layout data corresponding to the failure node candidate. Additionally, it has a display emphasis function that distinguishes this graphics group by means of a different intensity or color from surrounding graphics. There is already practically usable software corresponding to the above-noted operation of the layout display means 1.

Additionally, the critical area calculation means 4, by accessing the relationship between the mask layout data of the target LSI device included in the design data 3 and the size and density of occurrence of the extraneous materials including in the extraneous material distribution information 6, calculates the critical area of the failure node candidate, the results of this calculation being displayed by the critical area information display means 5. The displayed critical area information is support information, which indicates to be checked by physical means, of the failure node candidates.

The operation of this embodiment of the present invention is as follows.

First, the critical area will be described. The term critical area refers to a quantitative index indicating the degree to which a defect such as an extraneous material causes a short fault or an open fault.

For example, if an extraneous material becomes attached between interconnects, there is a possibility of a short occurring between the interconnects, but the degree of this possibility is governed by the spacing between the interconnects and the size (thought to be the diameter, assuming a circular shape) of the impurity.

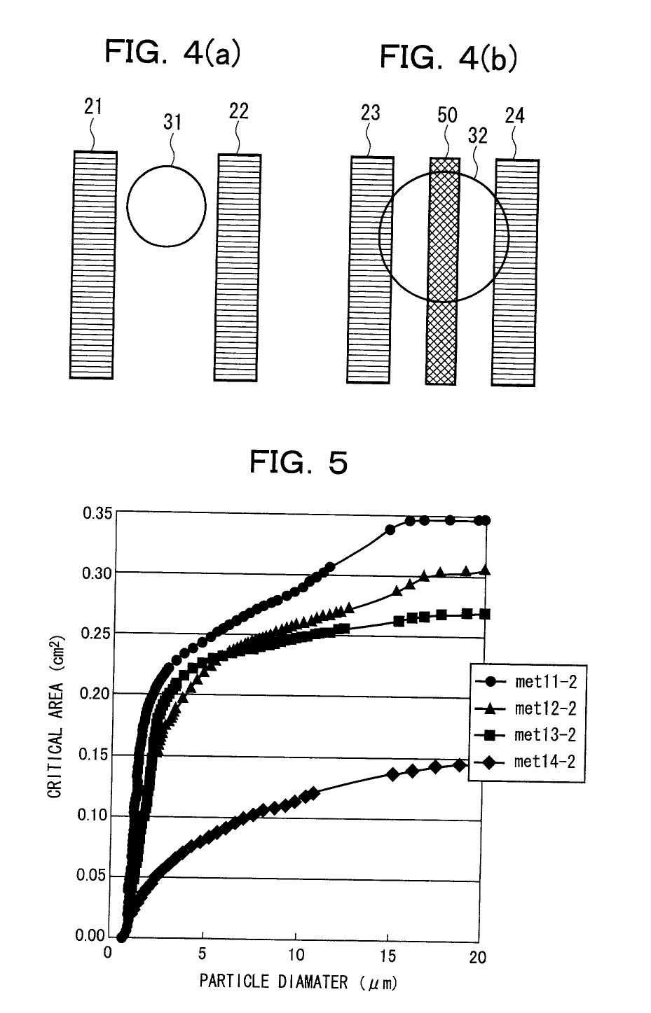

As shown in FIG. 4(a), although a short does not occur if the diameter of the extraneous material is smaller than the spacing between the interconnects, if it is larger than the spacing between the interconnects, whether or not a short occurs is determined by the positional relationship of the center coordinates of the extraneous material to the interconnects. Stated differently, a short will only occur in a case in which the center of an extraneous material is located within a specific region, and this region or the surface area thereof is referred to as the critical area. The critical area 50 shown in FIG. 4(b) corresponds to this area.

A case can be envisioned in which a short occurs within one and the same interconnect layer, and another case can be envisioned in which a short exists between different interconnect layers. In either case, considering a given interconnect layer the area within which an extraneous material would cause a short in that interconnect layer is defined as the critical area. The general approach is to calculate the critical areas over the entire surface of a chip for the interconnect layer of interest. For example, the critical area for shorts between the first interconnect layers of the chip is calculated.

As can be seen from the description above, the critical area is a function of the extraneous material size. Thus, if the condition of a critical area is graphed for each interconnect layer of a given chip, the results would be as shown in the example of FIG. 5. This example is one showing a critical area related to a short between one and the same interconnect layer of each of four interconnect layers.

Two methods have been reported for calculating such as critical area.

One method is that of applying a polygon operation, and the other is that of using a Monte Carlo simulation.

In the method of performing a polygon operation, this method causes neighboring interconnects to overlap by increasing the width of neighboring interconnects by the radius of extraneous materials, then overlapped portions are defined as critical area.

In the Monte Carlo simulation method, extraneous materials of random diameter are generated at random positions. This method is called dot-throwing technique as well since extraneous materials are thrown onto a mask layout by means of simulation. By generating a large number of virtual extraneous materials, so as to calculate the proportion of extraneous materials causing shorts, it is possible to use the calculated value as an approximation of the critical area normalized with respect to the chip surface area.

The two above-noted methods of calculating the critical area are reported, for example, in Proceedings of the Ninth International Symposium on Semiconductor Manufacturing, Sep. 26-28, 2000, pp. 191-194.

It is inconvenient, however, to deal with the value remaining in the form of a function of extraneous material size. For this reason, consider the effective critical area described below.

As can be understood from the description of the critical area, this is a monotonously increasing function with respect to the extraneous material size, and FIG. 5 illustrates this as well.

However, the number of actually exiting extraneous materials becomes smaller as the size increases. If an extraneous material size is x and it's density (number of extraneous material per unit surface area) is D(x), it is empirically known that D(x)∝x^{-P}. Additionally, p=3 is a good approximation.

Given the above, the product of the function D(x) and the critical area (as noted above, because this is a function of the extraneous material size, this is represented as Ac(x)), and the value obtained by performing an integration over a range above the minimum value of x is taken as the effective critical area, this being expressed by the following relationship.

Effective critical area=∫Ac(x) D(x) dx

The above integral is evaluated over the range of x0 (minimum x value, obtained as in-line data in the process step of interest) to infinity. D(x) is included in the extraneous material distribution information collected on the production line.

By defining this effective critical area as the critical area for one interconnect layer, it is possible to express a critical area with regard to one interconnect layer (for example, in the case of a short) as a single quantity, which is easy to handle.

A feature of the present invention is that the critical area is calculated for each node of interest as a failure node candidate. A node is generally formed by connecting a plurality of interconnect segments by means of contact or via holes. Therefore it is necessary to calculate the critical area for each interconnect segment, and add together the calculated critical areas.

In this case, the critical area also refers to the above-described effective critical area. That is, the critical area as used in the present invention, including the present invention as recited in the attached claims, is the effective critical area.

The calculation of the critical area as a function of the extraneous material size, required for calculating the effective critical area, can be performed by the method of polygon operation with respect to the interconnect segments of interest, or by the Monte Carlo simulation method, over certain region that includes the interconnect segment of interest, using the dot-throwing technique.

Because the critical area is an index that indicates the likelihood that a fault such as a short or an open will occur, it can serve also as an indicator of the certainty of a failure node candidate displayed in emphasize manner by the layout display means actually being a failure node. Thus, by displaying the critical area of a failure node candidate, it is possible to obtain information that serves to effectively indicate from the plurality of failure node candidates listed in the failure node candidate list 2 a narrowed-down list of failure node candidates that should be checked using a physical means such as a SEM.

The effective critical area can be displayed as a value, on a screen display.

In the case of an analysis operator with sufficient experience, even numerical information can be thought of as being useful in narrowing down the candidates.

It is alternatively possible and effective to display a graph over the mask layout to which is imparted an attribute, such as an intensity or display color, responsive to the effective critical area value as shown in FIG. 2. In FIG. 2, the numerals 12, 13, 14 denote interconnects on the LSI device, and the numeral 11 denotes an effective critical area indicated according to the present invention.

Additionally, in the case, for example, of an analysis operator without sufficient experience, it is possible to display a two-dimensional scatter diagram, which indicates the correlation between each failure node candidate frequency of occurrence and the corresponding effective critical area. Between the frequency of occurrence and the effective critical area, it can be envisioned that the correlation relationship such as shown in FIG. 3 exists. This is because extraneous materials generally occur randomly.

Nodes in accordance with this correlation relationship are ones at which there is a tendency for a failure to occur because of congestion of interconnects, and it can be expected that by taking measures to suppress extraneous materials it is possible to reduce the occurrence of failures. These can be thought of as predictable failures.

In contrast to the above, for a node at which an failure occurs because of an idiosyncratic cause in a mask layout data or a production process, if there is high repeatability, this phenomenon would be removed from the above-noted correlation relationship, such as shown by the point X in FIG. 3.

With regard to a failure node, in order to determine the cause of the failure at a failure node, it is necessary to use a physical means such as aSEM.

Another embodiment of the present invention is described below.

In this embodiment, the effective critical areas are calculated by selecting an arbitrary number of failure node candidates and calculating the effective critical area for each interconnect layer the linear combinations thereof, and setting up an equation with the these linear combinations being equivalent to the frequencies of occurrence. For example, for the case in which a failure node candidate consists of interconnect layers from the first to the third interconnect layers, the resulting equation would be

D₁·A_{c1}+D₂·A_{c2}+D₃·A_{c3}=k₁·F₁.

In the above, A_{c1}, AC_{c2}, and A_{c3} are the effective critical areas for each interconnect layer, D₁, D₂, and D₃ are the coefficient of combination, F₁ is the frequency of occurrence, and k₁ is a proportional constant. In this case, the coefficients of combination are taken as unknowns, because the same type of equations can be set up with regard to the other two failure node candidates, a set of simultaneous equations is obtained. The values of D₁, D₂, and D₃ obtained by solving these equations indicate the weights imparted to the failure at each interconnect layer process step, and it is possible to predict which process step is causing the failures.

It can be envisioned that, by collecting position information of extraneous materials on the LSI device using an in-line inspection apparatus and causing collected information to include within extraneous material distribution information 6, then the layout display means 1 displays collected information on the layout display so as to indicate the positions of the extraneous materials on the LSI device, it is possible to use the positional relationship between an actual extraneous material and an interconnect as support information in narrowing down the failure node candidates.

As described above, according to an LSI device failure analysis apparatus of the present invention, it is possible not only to make an overlaid display of the failure node candidates on the layout display, but also to use the critical area of a failure node candidate as support information in narrowing down the failure node candidates.

According to the present invention, in a failure analysis apparatus that provides an emphasized display of predicted failure nodes on a mask layout display for a logic LSI device, it is possible to use a critical area, which is an indicator of the likelihood of a failure occurring, as a support in narrowing down the failure node candidates. By doing this, it is possible not only to reduce the number of failure node candidates that are to be investigated using physical means involving a high cost, but also to reduce the number of analysis process steps.

Furthermore, it will be understood that the present invention is not restricted to application as noted in the exemplary embodiments described above, and can be applied in various other forms and variations, within the technical concept of the present invention.

What is claimed:

1. An LSI device failure analysis apparatus comprising:
a layout data of an LSI device,
failure node candidate data for a plurality of said LSI devices,
extraneous material distribution information on a production line of said LSI device,
a critical area calculation means for calculating a critical area corresponding to an arbitrary failure node of a failure node candidate data, by accessing said layout data and said extraneous material distribution information, and
a critical area information display means for displaying said calculated critical area.

2. The LSI device failure analysis apparatus according to claim 1, wherein said critical area information display means displays a value of a critical area.

3. The LSI device failure analysis apparatus according to claim 2, wherein said critical area information display means displays said critical area by means of different intensity or color from surrounding graphics in response to said value of said critical areas.

4. The LSI device failure analysis apparatus according to claim 1, wherein said critical area information display means calculates a frequency of occurrence of each failure node candidate of said failure node candidate data, and said critical area information display means displays a two-dimensional scatter diagram showing a relationship between said critical area and said frequency of occurrence of a corresponding failure node candidate.

5. The LSI device failure analysis apparatus according to claim 1, wherein said critical area information display means calculates a frequency of occurrence of each failure node candidate of said failure node candidate data, and said critical area calculation means calculates a critical area for each interconnect layer.

6. The LSI device failure analysis apparatus according to claim 5, wherein by selecting an arbitrary number of failure node candidates from said failure node candidate data and establishing an equation with regard to each of said selected failure node candidate in which a linear combination of each of said critical areas for each interconnect layer is equivalent to said frequency of occurrence, and setting up simultaneous equations having combination coefficients of said linear combinations as unknowns and said combination coefficients obtained by solving said equations are taken as predicted amount of faults in each interconnect layer.

7. The LSI device failure analysis apparatus according to claim 1, wherein said extraneous material distribution information includes size information of said extraneous material and density information thereof.

8. The LSI device failure analysis apparatus according to claim 1, wherein said extraneous material distribution information includes position information of said extraneous material on said LSI device.

9. The LSI device failure analysis apparatus according to claim 8, wherein said apparatus further comprising a layout display means for displaying a layout of said LSI device, an arbitrary number of failure node candidates of said LSI device overlaid onto said layout and position information of an arbitrary number of said extraneous material overlaid onto said layout, based on said extraneous material distribution information.

10. A failure analysis method of the LSI device failure analysis apparatus comprising:
a layout data of an LSI device,
failure node candidate data for a plurality of LSI devices that are same devices,
extraneous material distribution information on a production line of said LSI device,
said method comprising the steps of:
calculating a critical area corresponding to an arbitrary failure node of said failure node candidate data, by accessing said layout data and said extraneous material distribution information, and
displaying said calculated critical area.
